(19) United States
(12) Patent Application Publication
(10) Pub. No.: US 2006/0292310 A1
(43) Pub. Date: Dec. 28, 2006

(54) Process kit design to reduce particle generation

(75) Inventors: Hien-Minh Huu Le, San Jose, CA (US); Makoto Inagawa, Palo Alto, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/167,377

(22) Filed: Jun. 27, 2005

(51) Int. Cl. B05D 1/08; C23C 16/00

(52) U.S. Cl. 427/446; 118/715

(57) ABSTRACT

A method for making a process kit and a process kit design which has reduced particle generation during substrate processing are provided. The internal surface of the process kit design are textured by coating its surface with a first material layer having a smaller RMS surface roughness measurement and arc spraying with a second material layer or additional material layers having a larger RMS value. The first material layer can be coated by bead blasting, plating, arc spraying, thermal spraying, or other processes. In addition, the invention also provides selective coating of internal surface of the process kit with a protective layer and arc spraying the surface pf the protective layer with another material layer, which may be of the same material as the material of the internal surface of the process kit.

### BACKGROUND OF THE INVENTION

1. Field of the Invention

Embodiments of the present invention generally relate to a method to modify the surface of a material part used in a process chamber. More particularly, embodiments of the present invention relate to modifying the surface of chamber components used in a process chamber to provide a textured surface thereon.

2. Description of the Related Art

As electronic devices and integrated circuit devices continue to be fabricated with reduced dimensions, the manufacture of these devices becomes more susceptible to reduced yields due to contamination. Particularly, fabricating those devices having smaller device sizes requires the control of contamination to a greater extent than previously considered to be necessary.

Contamination of these devices may arise from sources including undesirable stray particles impinging on a substrate during thin film deposition, etching or other semiconductor wafer or glass substrate fabrication processes. In general, the manufacturing of the integrated circuit devices includes the use of process kits or chambers, such as physical vapor deposition (PVD) and sputtering chambers, chemical vapor deposition (CVD) chambers, plasma etching chambers, etc. During the course of deposition, etching and other processes, materials often condense from gas phase or any other phases onto various internal surfaces inside the process chamber to form solid masses that reside on these surfaces of the process chamber. These condensed foreign particles or contaminants accumulating on the internal surfaces of the process chamber are prone to detaching or flaking off onto the surface of the substrate in between or during a substrate processing sequence. These detached foreign particles may then impinge upon and contaminate the substrate and devices thereon. Contaminated devices frequently must be discarded, thereby decreasing the manufacturing yield of the substrate processing.

The contamination problem is much more severe when a large area substrate is being processed. For example, for processing substrates such as flat panels, the sizes of the substrates often exceed 370 mm×470 mm and sometimes range over 1 square meter in size. Large area substrates that are 4 square meters or larger are envisioned in the near future. Such large area substrates require a much larger area on the substrates to be free of particle contamination during substrate processing within a process chamber.

In order to prevent detachment of condensed foreign matter from internal surfaces of the process chamber, the internal surfaces may be textured into a rough surface such that the condensed foreign matter adheres better to these internal surfaces and is less likely to flake off, delaminate, and detach from the internal surfaces of the process chamber and fall onto and contaminate a substrate surface. As shown in FIG. 1A, a foreign material 102, such as condensed process materials and contaminants, may adhere to a surface of a work-piece 100, such as internal surfaces inside a process chamber during processing of a substrate. A textured coating 120 is provided to improve the adhesion of the foreign material 102 to the surface of the work-piece 100, as shown in FIG. 1B, but the thin layer of the textured coating 120 having a not so rough surface may not provides enough bonding/adhesion between the foreign material 102 and the surface of the work-piece 100. FIG. 1C demonstrates that a textured surface coating 130, being of a larger grain size and/or a rougher finish than the textured coating 120, may adhere better to and attract more of the foreign material 102, thereby providing less delamination of the foreign material 102. However, there are void spaces 140 underneath the thick textured surface coating 130. Thus, the textured surface coating 130 does not adhere strong enough to the surface of the work-piece 100 and a thick textured coating is not suitable due to its intrinsic high internal stress.

Methods currently used to texture chamber internal surfaces include “bead blasting.” Bead blasting includes spraying hard particles onto the surface under compressed/high pressure conditions in order to obtain a roughened surface, as shown in FIG. 1B and 1C. However, the bonding strength is typically low and internal surfaces of the process chamber need to be re-blasting or re-textured after only a few times of substrate processing.

Alternatively, the chamber internal surface may be texturized by spraying a coating to the surface, such as a thin coating of aluminum deposited by aluminum arc spray. Arc spray typically involves striking a DC electric arc between two continuous, thin consumable metal wire electrodes to form spray materials which are atomized by a jet of compressed gas into fine droplets and propelled onto a substrate surface, resulting in a low cost and high deposition rate spraying process. Other thermal spraying processes are also available for surface texturing. However, these and other methods for providing textured internal surfaces within a process chamber are sometimes ineffective at creating sufficient adhesion or bonding between the condensed masses and the chamber internal surface.

In order to circumvent the problems associated with delaminating and flaking foreign matter, chamber surfaces require frequent and sometimes lengthy cleaning steps to remove condensed masses from the chamber internal surfaces, such as chemically removing the condensed masses by various chemical solutions, and re-texturing the surfaces. Also, despite the amount of cleaning that is performed, in some instances contamination of delaminated, condensed materials onto the substrate during substrate processing in a process chamber may still occur. Further, when various chamber parts and chamber walls are made from aluminum, aluminum arc spray may not be suitable since the texturing material and the chamber material are the same, and cleaning and re-texturing the internal surfaces of the process chamber will affect the integrity and thickness of the chamber components.

Therefore, there is a need to reduce contamination of condensed foreign matter onto the interior surfaces of a process chamber and a need to develop a method for providing a rough textured surface with reduced stress to improve the adhesion of condensed foreign matter.

### SUMMARY OF THE INVENTION

The present invention generally provides a method of providing a very rough texture to a surface of a work-piece. In one embodiment, the method includes coating one or more surfaces of one or more components of the process chamber with a first material layer having a surface roughness measurement of a first dimensional root mean square (RMS) of about 1200 micro-inches or less and arc spraying the surface of the first material layer with a second material layer having a surface roughness measurement of a second RMS of about 1500 micro-inches or more to roughen the surface of the one or more components.

In another embodiment, a method of texturing a surface of a component for use in a semiconductor process chamber includes coating the surface of the work-piece with a first material layer having a surface roughness measurement of a first RMS and arc spraying the surface of the first material layer with a second material layer having a surface roughness measurement of a second RMS of about 1500 micro-inches or more to roughen the surface of the work-piece. The second RMS is larger than the first RMS.

In still another embodiment, a method of texturing a surface of a component for use in a semiconductor process chamber is provided. The method includes coating the surface of the component with a first material layer having a surface roughness measurement of a first RMS of about 1200 micro-inches or less and arc spraying the surface of the first material layer with a second material layer having a surface roughness measurement of a second RMS to roughen the surface of the component, the second RMS being larger than the first RMS.

Also provided is a method of reducing contamination in a process chamber. The method includes coating the surface of the component with a protective layer having a surface roughness measurement of a first RMS and arc spraying the surface of the protective layer with a material layer having a surface roughness measurement of a second RMS. The material layer may include the same material as the material of the component and the second RMS may be larger than the first RMS.

In another embodiment, a method of reducing contaminants in a process chamber includes coating one or more surfaces of one or more components of the process chamber with two or more material layers including a first material layer and a last material layer and texturing the one or more surfaces of the one or more components of the process with the last material layer by arc spraying to roughen the one or more surfaces of the one or more components, wherein the first material layer having a surface roughness measurement of a first RMS of about 1200 micro-inches or less and the last material layer having a surface roughness measurement of a second RMS of about 1500 micro-inches or more.

Further provided is a process chamber component for use in a process chamber. The process chamber component includes a body having one or more surfaces and a first coating formed on the surfaces, the first coating having a first RMS surface roughness measurement of about 1200 micro-inches or less. The process chamber component further includes a second coating formed on the surfaces by arc spraying, the second coating having a second RMS surface roughness measurement of about 1500 micro-inches or more to roughen the surface of the component. The second RMS may be larger than the first RMS.

The process chamber component may be a component of a PVD chamber for processing a large area flat panel display substrate. In one embodiment, the process chamber component is a chamber shield member, a dark space shield, a shadow frame, a substrate support, a target, a shadow ring, a deposition collimator, a chamber body, a chamber wall, a coil, a coil support, a cover ring, a deposition ring, a contact ring, an alignment ring, or a shutter disk, among others.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates impinging or condensation of a material onto a surface of a work-piece.

FIG. 1B illustrates using a textured coating to improve adhesion of a material onto a surface of a work-piece.

FIG. 1C illustrates applying a very rough surface coating to improve adhesion of a material onto a surface of a work-piece.

FIG. 2 illustrates a flow diagram of one exemplary method according to one embodiment of the invention.

FIG. 3 illustrates a flow diagram of another exemplary method according to another embodiment of the invention.

FIG. 4 illustrates a schematic cross-sectional view of one embodiment of an exemplary textured surface using methods of the invention.

FIG. 5 illustrates a schematic cross-sectional view of an exemplary process chamber having textured internal surfaces according to one embodiment of the invention.

FIG. 6A illustrates a horizontal top view of exemplary process chamber components having textured internal surfaces according to one embodiment of the invention.

FIG. 6B illustrates a schematic view of exemplary ground shield and ground frame having textured internal surfaces according to one embodiment of the invention.

FIG. 7A illustrates a schematic view of one exemplary shadow frame having textured surfaces according to one embodiment of the invention.

FIG. 7B illustrates a schematic view of exemplary shadow frame, chamber shield, and chamber body having textured surfaces according to one embodiment of the invention.

FIG. 8 illustrates a schematic view of an exemplary substrate support of a process chamber according to one embodiment of the invention.

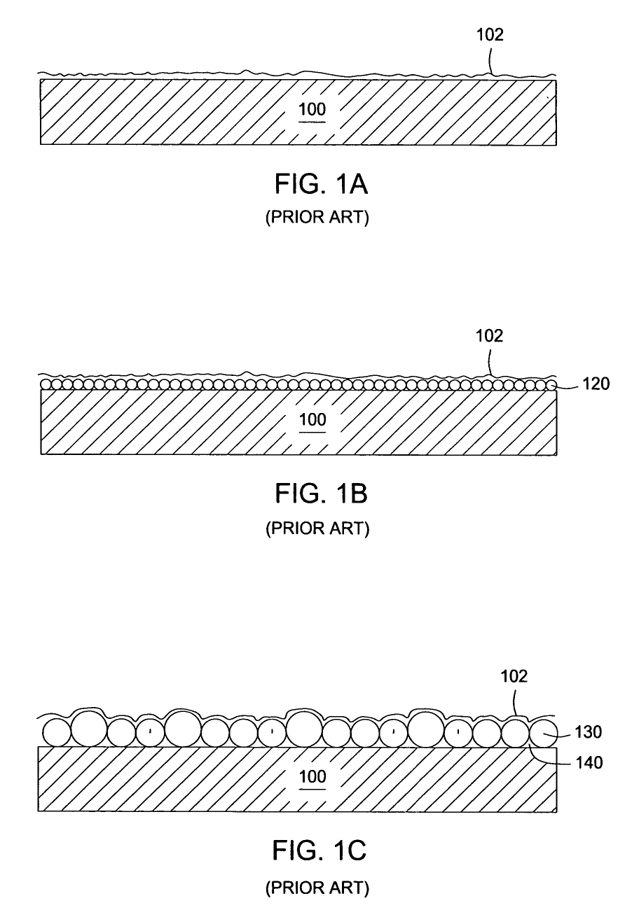

### DETAILED DESCRIPTION

The present invention provides a method of providing a very rough-textured surface to a work-piece. A well-textured surface reduces the possibility of condensed materials flaking from the work-piece. For example, the work-piece may include various internal components/parts of a process chamber or a process kit such that rough internal surfaces of the process chamber can be used to attract and adhere various particles, condensed materials, contaminants generated during substrate processing. The invention further provides the process chamber and various chamber components having rough textured surfaces.

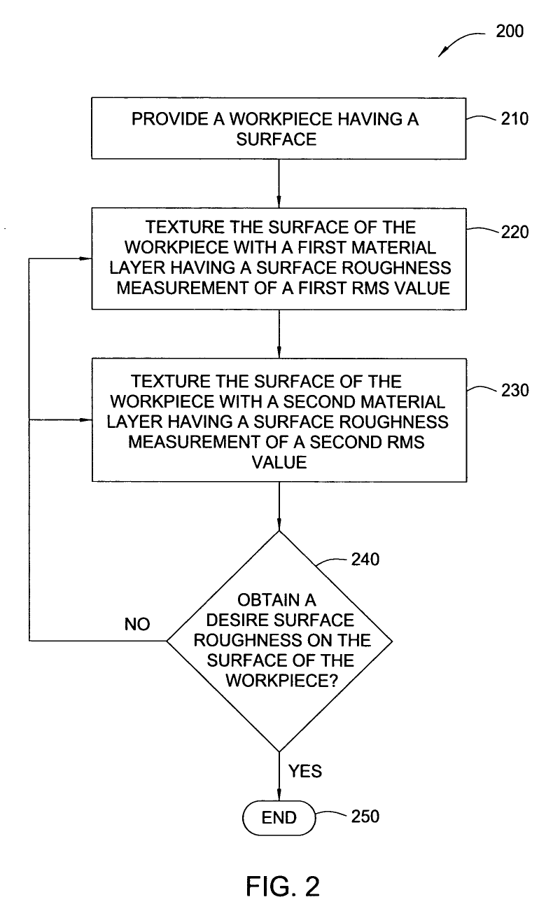

FIG. 2 illustrates a flow chart of a method 200 according to one embodiment of the invention to provide a very rough texture to a surface of a work-piece. At step 210, the work-piece having a surface is provided. The work-piece generally includes a material, such as a metal or metal alloy, a ceramic material, a polymer material, a composite material, or combinations thereof. For example, the work-piece includes aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof. In one embodiment, the work-piece comprises an austenitic-type steel. In another embodiment, the work-piece comprises aluminum.

At step 220, the surface of the work-piece is textured with a first material layer having a surface roughness measurement of a first root mean square (RMS) value. Surface roughness is usually measured in micro-inches or dimensional root mean square (RMS) by means of a profilometer. In addition, the thickness of the first material layer can be verified by an eddy current measuring device. The first RMS value for the first material layer may be about 1500 Ra or micro-inches or less, such as about 1200 micro-inches or less, or about 500 micro-inches or less, e.g., about 300 micro-inches to about 1200 micro-inches.

Texturing a surface can be performed by any of film coating processes known in the art, such as thermal spray coating, plating, bead blasting, grit blasting, powder coating, airless spray, electrostatic spray, etc. For example, arc spraying, flame spraying, powder flame spraying, wire flame spraying, plasma spraying, among others, can be used to adjust the surface roughness of the first material layer coated by the above-mentioned film coating processes according to embodiments of the invention.

For example, aluminum arc spraying a work-piece surface can be performed to have an average surface roughness measurement of about 1000 micro-inches. Preferably, a first RMS value of about 800 micro-inches or less, such as about 500 micro-inches or less, after arc spraying a first material onto the work-piece is obtained to provide a thin and even coating for bonding and coating the first material to the surface of the work-piece with less internal stress and as a good basis for another material layer to be coated thereon.

The first material layer may include a material such as aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof. In one embodiment, the first material layer comprises aluminum or its alloy. In another embodiment, the first material layer comprises molybdenum or its alloy.

At step 230, the surface of the work-piece is textured with a second material layer having a surface roughness measurement of a second RMS value. The second RMS value for the second material layer may be about 1200 micro-inches or more, such as about 1500 micro-inches or more, e.g., between about 2000 micro-inches and about 2500 micro-inches or more. Preferably, the second RMS is larger than the first RMS such that a very rough surface of the work-piece can be obtained without the disadvantage of large internal stress associated with one thick coating layer.

The second material layer may be coated by any of film coating processes known in the art. As an example, arc spraying provides a very cost-effective way to texture the work-piece surface and deposit the second material layer with high deposition rate. Generally, a deposition rate of about 6 kilograms per hour to about 60 kilograms per hour can be obtained.

In addition, the second material layer may be of the same or different materials as the first material layer. In one embodiment, the invention provides that the first and the second material layers are of the same material such that the surface roughness measurement on the work-piece surface can be increased layer-by-layer by the first, second, and more material layers to provide strong bonding to the work-piece surface and between first and second material layers. Thus, a final rough and thick material coating with reduced internal stress can be obtained.

In another embodiment, the first and the second material layers may be of different materials. This is useful when the work-piece and the textured second material layer (or any final material layers on the surface) are of the same material. In this case, the first material layer can be provided as a glue layer between the work-piece and the second material layer to provide desired roughness and texture on the surface of the work-piece. For example, when the work-piece comprises a pure metal material, the first material may be its alloy and the second material may be the same metal material. One example of such metal is aluminum. Another example includes that the work-piece and the second material layer comprises aluminum or its alloys, the second material layer having large RMS value of between about 2000 micro-inches and about 2500 micro-inches, and the first material layer comprises a different metal material or its alloys thereof with smaller RMS surface measurement of about 500 micro-inches or less.

The method 200 further includes coating or depositing one or more additional material layers to the surface of the work-piece until a desired surface roughness is obtained at step 240 and the method ends at step 250. For example, the steps 220 and/or 230 can be repeated if the surface roughness of the surface of the work-piece is not acceptable.

In addition, one or more surface treatments can be performed prior to, during, or after texturing the surface of the work-piece. For example, the work-piece may be heated to provide ease of one or more coating and texturing steps by using a radiant heat lamp, inductive heater, or an IR type resistive heater. As another example, the work-piece may be chemically cleaned prior to, during, or after texturing the surface of the work-piece using any of the cleaning solutions known in the art, such as a distilled water solution, a sulfuric acid solution, a hydrofluoric acid (HF) solution, among others.

The method 200 may further include processing a substrate in a process chamber to generate condensed particles, contaminants, foreign materials, etc., which bind to the second material layer on the surface of the work-piece. In addition, the surface of the work-piece may be chemically cleaned in order to remove any of the particles and condensed foreign materials using cleaning or etching solutions, for example, distilled water solution, a sulfuric acid solution, a hydrofluoric acid solution, etc. In some cases, the rough surface texture of the work-piece may also be cleaned or etched away partially or completely by the cleaning/etching solution. For example, the second material may be removed, and in one embodiment of the invention, the surface of the work-piece is re-textured using methods of the invention.

It is especially important to texturing and re-texturing one or more internal surfaces of a process chamber when processing a large area substrate, such as a substrate for flat panel display, to prevent and reduce particle generation onto the large area substrate during substrate processing. However, the invention is equally applicable to substrate processing of any types and sizes. Substrates of the invention can be circular, square, rectangular, or polygonal for semiconductor wafer manufacturing and flat panel display manufacturing. The surface area of a rectangular substrate for flat panel display is typically large, for example, a rectangle of about 500 mm² or larger, such as at least about 300 mm by about 400 mm, e.g., about 120,000 mm² or larger. In addition, the invention applies to any devices, such as OLED, FOLED, PLED, organic TFT, active matrix, passive matrix, top emission device, bottom emission device, solar cell, etc., and can be on any of the silicon wafers, glass substrates, metal substrates, plastic films (e.g., polyethylene terephthalate (PET), polyethylene naphthalate (PEN), etc.), plastic epoxy films, among others.

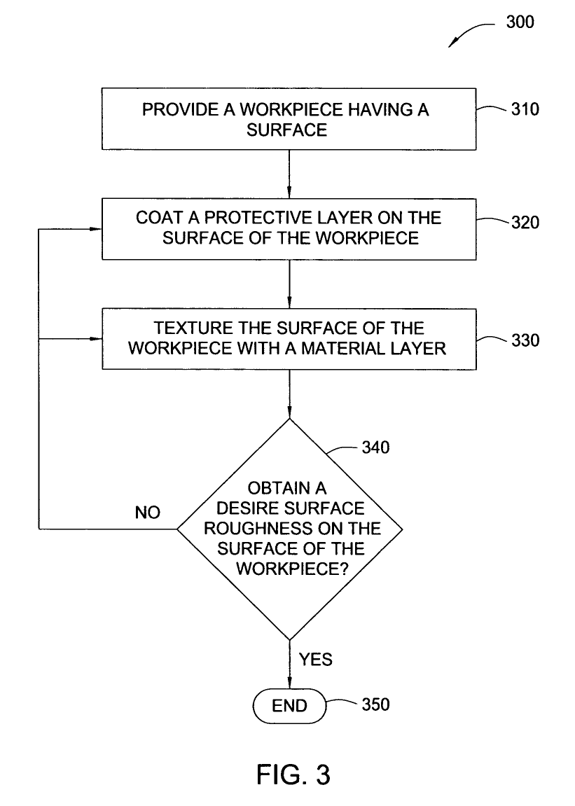

FIG. 3 illustrates a flow chart of a method 300 according to another embodiment of the invention to provide a very rough texture to a surface of a work-piece. At step 310, the work-piece is provided. At step 320, the surface of the work-piece is coated with a protective layer. The protective layer may have a first RMS value of about 1500 micro-inches or less, such as about 1200 micro-inches or less, or about 500 micro-inches or less.

Coating the protective layer to the desired surface roughness on the work-piece surface can be performed by any of film coating processes known in the art, such as thermal spray coating, plating, bead blasting, grit blasting, powder coating, airless spray, electrostatic spray, arc spraying, flame spraying, powder flame spraying, wire flame spraying, plasma spraying, among others. The protective layer may include a material such as aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.

At step 330, the surface of the work-piece is textured with a material layer. Preferably, the protective layer and the material layer are of different materials. The material layer may be formed by any of film coating processes known in the art to the desired surface roughness. For example, arc spraying provides a very effective way to for the material layer. However, other spray coating, plating, bead blasting processes can also be used. The material layer at step 330 may have a surface roughness measurement of a second RMS value at about 1200 micro-inches or more, such as about 1500 micro-inches or more, e.g., between about 2000 micro-inches and about 2500 micro-inches. Preferably, the second RMS is larger than the first RMS such that a very rough surface of the work-piece can be obtained without the disadvantage of large internal stress associated with one thick coating layer.

The material layer at step 330 may be of a material different from the material of the protective layer at step 320 such that the work-piece is protected by the protective layer from any chemical reactions and/or solutions, such as any chemical cleaning or etching solution to prevent corrosion of the work-piece. For example, the material layer may include a material such as aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.

For example, the work-piece may first be coated with a protective layer of thin titanium by plating the work-piece in a titanium ion-containing electroplating solution. Over the surface of the work-piece, an aluminum layer or a molybdenum layer can be textured and coated thereon, such as by arc spraying. The titanium layer protects the work-piece from corrosion and any of the etching, removing and/or cleaning of the textured coating layer performed later.

As another example, the protective layer can be formed by arc spraying of an aluminum alloy onto the surface of the work-piece to protect the work-piece. A pure aluminum layer can then be textured onto the surface of the work-piece to provide a desired surface roughness to the work-piece. In still another example, the protective layer can be formed by arc spraying of a molybdenum alloy onto the surface of the work-piece to protect the work-piece. A pure molybdenum layer can then be textured onto the surface of the work-piece to provide a desired surface roughness to the work-piece.

The method 300 further include coating or depositing one or more additional material layers to the surface of the work-piece if a desired surface roughness is not obtained. Finally, if a desired roughness is obtained at step 340, the method can end at step 350. When a desired surface roughness is not obtained, then, the steps 320 and/or 330 can be repeated.

In addition, the method 300 may further include heating the work-piece prior to coating the protective layer, prior to texturing with the material layer, or after a desired surface roughness is obtained to promote the efficiency of the coating and texturing steps or provide annealing of the protective layer and the material layers. Similarly, the method 300 may further include chemically cleaning prior to or after any of the steps. In one embodiment, the method 300 further includes chemically cleaning the surface of the work-piece prior to coating the protective layer. In another embodiment, the method 300 further includes chemically cleaning the surface of the work-piece after arc spraying to remove the material layer. For example, cleaning can be performed using any of the cleaning or etching solutions appropriate for the material to be removed.

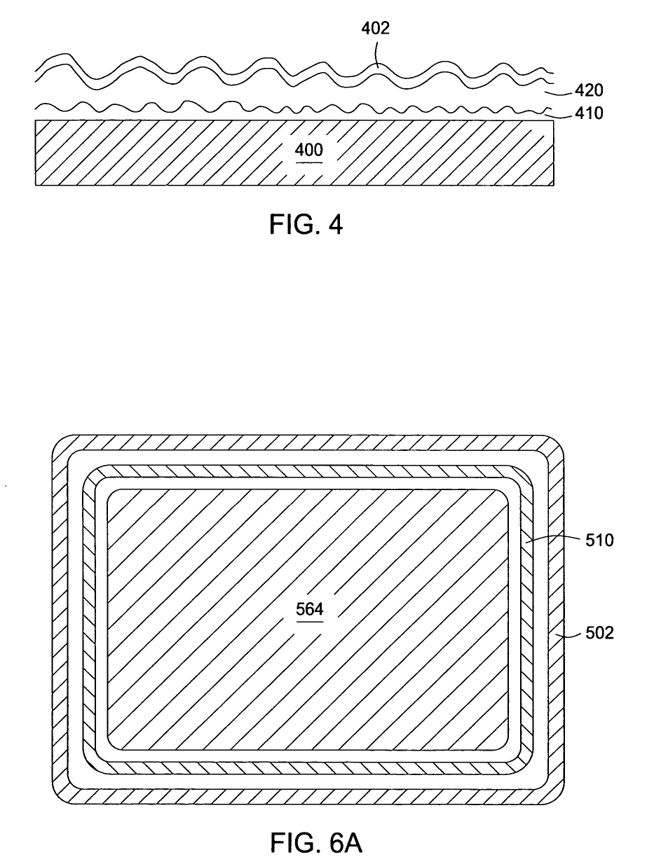

FIG. 4 illustrates a schematic cross-sectional view of an exemplary textured surface of a work-piece 400 using methods of the invention. The work-piece 400 may be any parts of a process kit or any components of a process chamber having one or more internal surfaces. Exemplary work-piece 400 includes a chamber shield member, a dark space shield, a shadow frame, a substrate support, a target, a shadow ring, a deposition collimator, a chamber body, a chamber wall, a coil, a coil support, a cover ring, a deposition ring, a contact ring, an alignment ring, a shutter disk, among others, which will be further described below. The process chamber may be physical vapor deposition (PVD) and sputtering chambers, ion metal implant (IMP) chambers, chemical vapor deposition (CVD) chambers, atomic layer deposition (ALD) chambers, plasma etching chambers, annealing chambers, other furnace chambers, etc. In a preferred embodiment, the chamber is a substrate process chamber in which a substrate is exposed to one or more gas-phase materials or plasma. The materials of various process chamber components may vary, including stainless steel or aluminum, among others.

As shown in FIG. 4, a first material layer 410 is coated on the surface of the work-piece 400. The first material layer may have a first RMS value of about 1200 micro-inches or less. A second material layer 420 can be formed on the surface of the first material layer 410. The second material layer may have a second RMS value of about 1500 micro-inches or more. The first material layer 410 and the second material layer 420 can be formed by any coating process known in the art, for example, both by an arc spraying process. Alternatively, the first material layer 410 and the second material layer 420 can be formed by different processes. For example, the first material layer 410 can be formed by a plating process and the second material layer 420 can be formed by an arc spraying process such that the second RMS is larger than the first RMS. In one embodiment, one or more additional layers may also be formed in between the first material layer 410 and the second material layer 420. In another embodiment, one or more additional layers with greater RMS values may also be formed onto the surface of the second material layer 420.

One aspect of the invention provides the use of at least two material layers, such as the first material layer 410 and second material layer 420, such that a desired surface roughness and texture is obtained to attract and adhere any condensed particles, contaminants, and/or foreign material 402 generated during substrate processing inside a process chamber onto the surface of the work-piece 400. Without the first material layer 410 of smaller RMS, the second material layer 420 may be delaminated easily from the surface of the work-piece 400. In addition, without the second material layer 420 of greater RMS, the first material layer 410 may not provide adequate bonding and enough adhesion to the foreign material 402.

Furthermore, when a large area substrate is processed by the process chamber, due to the large size of the process chamber, a material of less expensive and lighter weight is preferred to be used as the chamber interior walls and various components. Preferably, aluminum can be used to advantage. However, aluminum is not suitable as a direct surface texturing material since the chamber material and the texturing material, if both formed of an aluminum material, will both be chemically cleaned away. Thus, another aspect of the invention provides that the fist material layer 410 being of different material from the second material layer 420 in order to protect the work-piece 400 from any surface treatment, corrosion, or chemical cleaning. For example, when the same materials, such as aluminum, among others, are used as the material of choice for the work-piece and the second material layer, the first material layer 410 may be made of a different material, such as aluminum alloy, titanium, among others, as a protective layer for the work-piece. Therefore, the second material layer can provide better adhesion to the foreign material 402 so it is easier to be cleaned by a chemical cleaning or etching solution, and easier to re-apply or re-texture to the surface of the work-piece after cleaning, etching, or re-texturing.

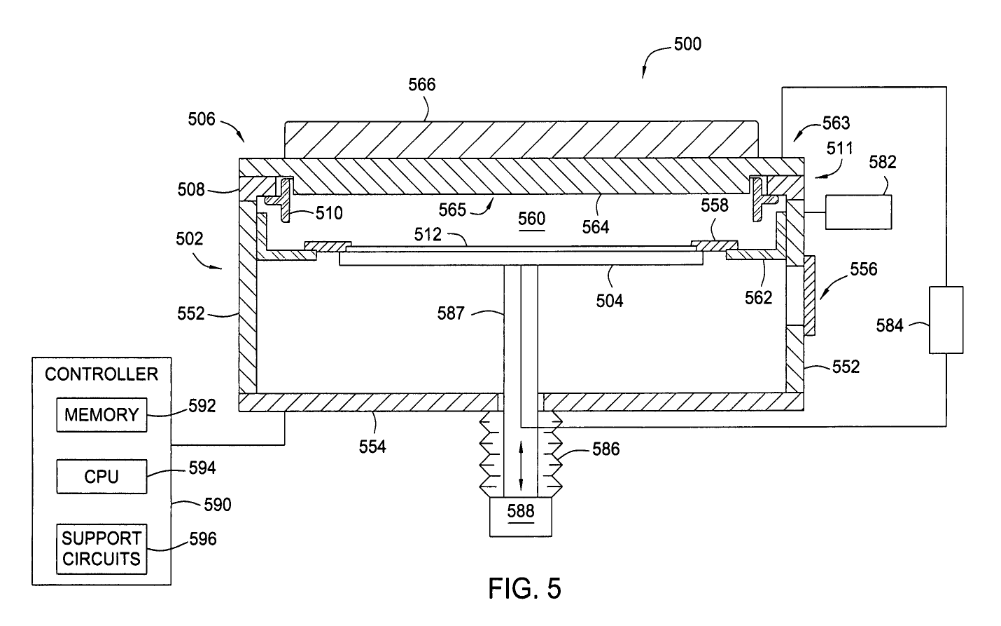

FIG. 5 illustrates a process chamber 500 having textured internal surfaces using methods of the invention according to one embodiment of the invention. Embodiments of the invention provides texturing of various chamber parts and components located in one or more internal surfaces of the process chamber 500 to reduce particle contamination within the process chamber 500 such that the particle contamination can adhere better to the one or more internal surfaces, easily cleaned away, and re-textured, if needed. One example of a process chamber 500 that may be adapted to benefit from the invention is a PVD process chamber, available from Applied Materials, Inc., located in Santa Clara, Calif.

The exemplary process chamber 500 includes a chamber body 502 and a lid assembly 506, defining a process volume 560. The chamber body 502 is typically fabricated from a unitary block of aluminum or welded stainless steel plates. The dimensions of the chamber body 502 and related components to be textured using method of the invention are not limited and generally are proportionally larger than the size and dimension of a substrate 512 to be processed in the process chamber 500. For example, when processing a large area square substrate having a width of about 370 mm to about 2160 mm and a length of about 470 mm to about 2460 mm, the chamber body 502 may include a width of about 570 mm to about 2360 mm and a length of about 570 mm to about 2660 mm. As one example, when processing a substrate size of about 1000 mm×1200 mm, the chamber body 502 can have a cross sectional dimension of about 1750 mm×1950 mm. As another example, when processing a substrate size of about 1950 mm×2250 mm, the chamber body 502 can have a cross sectional dimension of about 2700 mm×3000 mm.

The chamber body 502 generally includes sidewalls 552 and a bottom 554. The sidewalls 552 and/or bottom 554 generally include a plurality of apertures, such as an access port 556 and a pumping port (not shown). Other apertures, such as a shutter disk port (not shown) may also optionally be formed on the sidewalls 552 and/or bottom 554 of the chamber body 502. The access port 556 is sealable, such as by a slit valve or other mechanism, to provide entrance and egress of the substrate 512 (e.g., a flat panel display substrate or a semiconductor wafer) into and out of the process chamber 500. The pumping port is coupled to a pumping system (also not shown) that evacuates and controls the pressure within the process volume 560.

The lid assembly 506 generally includes a target 564 and a ground shield assembly 511 coupled thereto. The target 564 provides a material source that can be deposited onto the surface of the substrate 512 during a PVD process. The target 564 or target plate may be fabricated of a material that will become the deposition species or it may contain a coating of the deposition species. To facilitate sputtering, a high voltage power supply, such as a power source 584 is connected to the target 564. The target 564 generally includes a peripheral portion 563 and a central portion 565. The peripheral portion 563 is disposed over the sidewalls 552 of the chamber. The central portion 565 of the target 564 may protrude, or extend in a direction towards the substrate support 504. It is contemplated that other target configurations may be utilized as well. For example, the target 564 may comprise a backing plate having a central portion of a desired material bonded or attached thereto. The target material may also comprise adjacent tiles or segments of material that together form the target. Optionally, the lid assembly 506 may further comprise a magnetron assembly 566, which enhances consumption of the target material during processing.

During a sputtering process to deposit a material on the substrate 512, the target 564 and the substrate support 504 are biased relative each other by the power source 584. A process gas, such as inert gas and other gases, e.g., argon, and nitrogen, is supplied to the process volume 560 from a gas source 582 through one or more apertures (not shown), typically formed in the sidewalls 552 of the process chamber 500. The process gas is ignited into a plasma and ions within the plasma are accelerated toward the target 564 to cause target material being dislodged from the target 564 into particles. The dislodged material or particles are attracted towards the substrate 512 through the applied bias, depositing a film of material onto the substrate 512.

The ground shield assembly 511 includes a ground frame 508, a ground shield 510, or any chamber shield member, target shield member, dark space shield, dark space shield frame, etc. The ground shield 510 surrounds the central portion 565 of the target 564 to define a processing region within the process volume 560 and is coupled to the peripheral portion 563 of the target 564 by the ground frame 508. The ground frame 508 electrically insulates the ground shield 510 from the target 564 while providing a ground path to the chamber body 502 of the chamber 500 (typically through the sidewalls 552). The ground shield 510 constrains the plasma within the region circumscribed by the ground shield 510 to ensure that target source material is only dislodged from the central portion 565 of the target 564. The ground shield 510 may also facilitate depositing the dislodged target source material mainly on the substrate 512. This maximizes the efficient use of the target material as well as protects other regions of the chamber body 502 from deposition or attack from the dislodged species or the from the plasma, thereby enhancing chamber longevity and reducing the downtime and cost required to clean or otherwise maintain the chamber. Another benefit derived from the use of the ground frame 508 surrounding the ground shield 510 is the reduction of particles that may become dislodged from the chamber body 502 (for example, due to flaking of deposited films or attack of the chamber body 502 from the plasma) and re-deposited upon the surface of the substrate 512, thereby improving product quality and yield.

While the ground shield 510 generally confines the plasma and sputtered particles within the process volume 560, inevitably, sputtered particles, initially in a plasma or gaseous state, condense onto various interior chamber surfaces. For example, sputtered particles may condense on interior surfaces of the chamber body 502, the target 564, the lid assembly 506, and the ground shield assembly 511, as well as other interior chamber surfaces of one or more chamber components. Furthermore, other surfaces, such as the top surface of the substrate support 504 may become contaminated either during or in between deposition sequences. The chamber component may be a vacuum chamber component, i.e. a chamber component placed within a vacuum chamber, such as, for example, the process chamber 500. The condensed matter that forms on the interior surface of a chamber component, generally has only limited adhesion, and may release from the chamber component and contaminate the substrate 512. In order to reduce the tendency of condensed foreign matter to detach from a process chamber component, these chamber components are textured by the methods of the invention to reduce particle contamination onto the surface of the substrate 512.

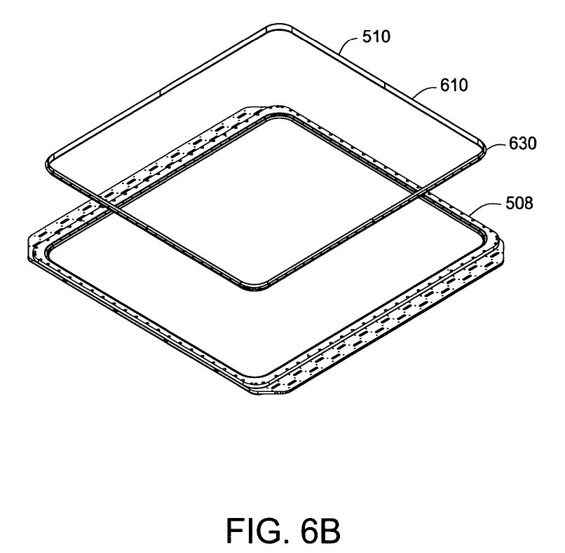

FIGS. 6A and 6B illustrate a horizontal top view of exemplary process chamber components having textured internal surfaces according to one embodiment of the invention. The ground shield 510, the ground frame 508, the target 564, any dark space shield, chamber shield member, shield frame, target shield member, among others, can be textured, cleaned and re-textured by the methods 200 and 300 of the invention to reduce particle contamination during a PVD process. In addition, as shown in FIG. 6A, the chamber body 502 including the sidewalls 552, the bottom 554, and other components can be textured. FIG. 6B illustrates a schematic view of the ground shield 510 and the ground frame 508 surrounding the ground shield 510, each having textured internal surfaces according to one embodiment of the invention. As shown in FIG. 6A, the ground shield 510 may be formed of one or more work-piece fragments 610 and one or more corner pieces 630, and a number of these pieces are bonded together, using bonding processes known in the art, such as welding, gluing, high pressure compression, etc. The invention further provides texturing individual work-piece, such as the work-piece fragment 610 and the corner piece 630, by the method 200 and 300 of the invention before they are bonded together to form into the ground shield 510.

The dimensions of the target 564, the ground shield 510, and the ground frame 508 and related components to be textured using method of the invention are not limited and are related to the size and shape of the substrate 512 to be processed. For example, when processing a large area square substrate having a width of about 1000 mm to about 2160 mm and a length of about 1200 mm to about 2460 mm, the target 564 may include a width of about 1550 mm to about 2500 mm and a length of about 1750 mm to about 2800 mm. As one example, the target 564 can have a cross sectional dimension of about 1550 mm×1750 mm. As another example, the target 564 can have a cross sectional dimension of about 2500 mm×2800 mm. In addition, the size of the ground shield 510 may be from about 1600 mm×1800 mm to about 2550 mm×2850 mm. Other smaller dimensions can also be used to advantages for smaller substrate sizes.

The ground shield 510 and other chamber component can be textured and bonded together to be attached to the lid assembly 506. One benefit of attaching the ground shield 510 to the lid assembly 506 is that the ground shield 510 and the target 564 may be more easily and accurately aligned prior to placing the lid assembly 506 on the chamber body 502, thereby reducing the time required to align the ground shield 510 with the target 564. However, other configurations can also be used. Once the ground shield 510 is attached to the lid assembly 506, the lid assembly 506 may simply be placed on the sidewalls 552 to complete the set up. Thus, the need to align the ground shield 510 and the target 564 after installation, as required in conventional chambers with adjustable target/ground shield arrangements, is eliminated. Moreover, the need for costly precise locating pins and/or parts, as required in conventional chambers that do not have adjustable target/ground shield arrangements, is also eliminated. Exemplary shield parts may include 0020-45544, 002047654, 0020-BW101, 0020-BW302, 0190-11821, 0020-44375, 0020-44438, 0020-43498, 0021-JW077, 0020-19122, 0020-JW096, 0021-KS556, 002045695 available from Applied Materials Inc., Santa Clara Calif.

Referring back to FIG. 5, the substrate support 504 is generally disposed on the bottom 554 of the chamber body 502 and supports the substrate 512 thereupon during substrate processing within the vacuum process chamber 500. The substrate support 504 may include a plate-like body for supporting the substrate 512 and any additional mechanism for retaining and positioning the substrate 512, for example, an electrostatic chuck and other positioning means. The substrate support 504 may include one or more electrodes and/or heating elements imbedded within the plate-like body support. A shaft 587 extends through the bottom 554 of the chamber body 502 and couples the substrate support 504 to a lift mechanism 588. The lift mechanism 588 is configured to move the substrate support 504 between a lower position and an upper position. The substrate support 504 is depicted in an intermediate position in FIG. 5. A bellows 586 is typically disposed between the substrate support 504 and the chamber bottom 554 and provides a flexible seal therebetween, thereby maintaining vacuum integrity of the chamber volume 560.

Typically, a controller 590 interfaces with and controls the process chamber 500. The controller 590 typically comprises a central processing unit (CPU) 594, support circuits 596 and memory 592. The CPU 594 may be one of any form of computer processor that can be used in an industrial setting for controlling various chambers and sub-processors. The memory 592 is coupled to the CPU 594. The memory 592, or computer-readable medium, may be one or more of readily available memory such as random access memory (RAM), read only memory (ROM), floppy disk, hard disk, or any other form of digital storage, local or remote. The support circuits 596 are coupled to the CPU 594 for supporting the processor in a conventional manner. These circuits include cache, power supplies, clock circuits, input/output circuitry, subsystems, and the like. The controller 590 may be used to control operation of the process chamber 500, including any deposition processes performed therein.

Optionally, a shadow frame 558 and a chamber shield 562 may be disposed within the chamber body 502. The shadow frame 558 is generally configured to confine deposition to a portion of the substrate 512 exposed through the center of the shadow frame 558. When the substrate support 504 is moved to the upper position for processing, an outer edge of the substrate 512 disposed on the substrate support 504 engages the shadow frame 558 and lifts the shadow frame 558 from the chamber shield 562. When the substrate support 504 is moved into the lower position for loading and unloading the substrate 512 from the substrate support 504, the substrate support 504 is positioned below the chamber shield 562 and the access port 556. The substrate 512 may then be removed from or placed into the chamber 500 through the access port 556 on the sidewalls 552 while cleaning the shadow frame 558 and the chamber shield 562. Lift pins (not shown) are selectively moved through the substrate support 504 to space the substrate 512 away from the substrate support 504 to facilitate the placement or removal of the substrate 512 by a wafer transfer mechanism or a robot disposed exterior to the process chamber 500, such as a single arm robot or dual arm robot.

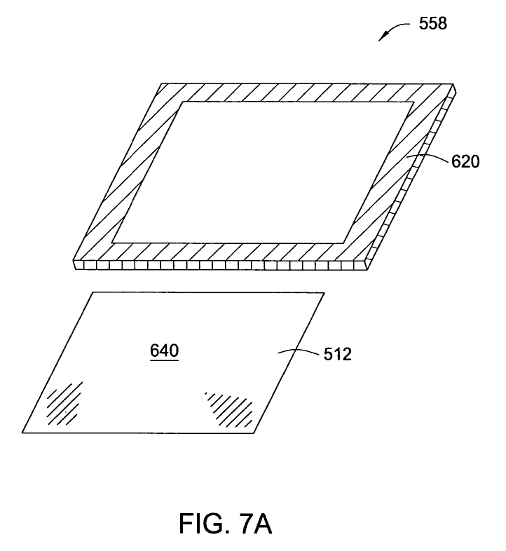

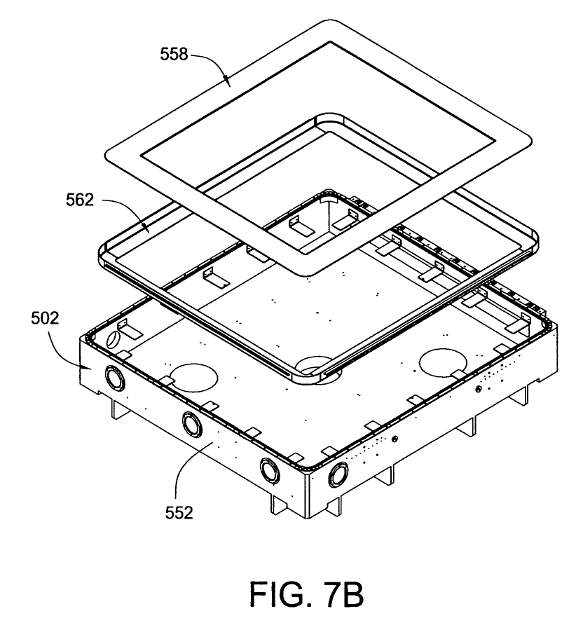

FIG. 7A illustrates a schematic view of the shadow frame 558 having textured surfaces according to one embodiment of the invention. The shadow frame 558 can be formed of one piece or it can be two or more work-piece fragments bonded together in order to surround the peripheral portion of the substrate 512. The shadow frame 558 can be textured to include the first and second material layers 410, 420 or additional layers on the surface in order to attract the foreign material 402 adhering thereon and prevent the foreign material 402 from contaminating the surface of the substrate 512. Preferably, an upper surface 620 or the surface facing the process volume 560 of the shadow frame 558 is textured with one or more material layers to prevent contamination of a processing surface 640 of the substrate 512. The shadow frame 558 may include an inner dimension which is selected so that the shadow frame 558 fits peripherally over the edge of the substrate 512. The shadow frame 558 includes an inner dimension smaller than the dimension of the substrate 512 and an outer dimension larger than the dimension of the substrate 512. For example, the shadow frame 558 may include an exemplary inner dimension of about 1930 mm×2230 mm and an exemplary outer dimension of about 2440 mm×2740 mm for a substrate size of about 1950 mm×2250 mm, such that a peripheral portion of the substrate 512 is shielded from particles and contaminants. Substrates of smaller sizes and other shapes can also be applied.

FIG. 7B illustrates a schematic view of the shadow frame 558, the chamber shield 562, the chamber body 502, and the sidewall 552 having textured surfaces according to one embodiment of the invention. The surfaces of all these chamber components as well as other components, such as substrate clamping structures used in other substrate processing chambers, can be textured according to embodiments of the invention. As shown in FIG. 7B, the shadow frame 558 rests upon the chamber shield 562 which may be coupled, for example, to the sidewalls 552 of the chamber body 502. Exemplary dimension of the chamber shield 562 may include an inner dimension of about 2160 mm×2550 mm and an outer dimension of about 2550 mm×2840 mm for a substrate size of about 1950 mm×2250 mm to support the shadow frame 558 positioned thereon. Alternatively, shadow frames having other configurations may optionally be utilized as well. Exemplary shadow frame, deposition frame, substrate cover structure, and/or substrate clamp include 0020-43171 and 0020-46649 available from Applied Materials Inc., Santa Clara Calif.

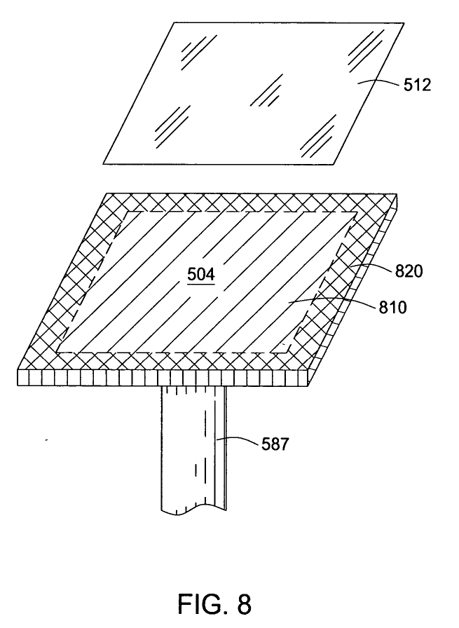

Another embodiment of the invention further provides that a portion of the substrate support 504 of the invention is textured according to methods described herein to reduce particle accumulation during substrate processing. FIG. 8 illustrates a schematic view of one example of the substrate support 504 of the process chamber 500. The substrate support 504 is typically fabricated from aluminum, stainless steel, ceramic or combinations thereof. The substrate support 504 on top of the shaft 587 includes an upper surface 810 to support the substrate 512 thereon. The upper surface 810 can be textured with the first and second material layers 410, 420 or additional layers on the surface in order to attract the foreign material 402 adhering thereon and prevent the foreign material 402 from contaminating the surface of the substrate 504.

The dimension of the upper surface 810 of the substrate support supporting the substrate 512 is proportional to the size of the substrate 512 and may be smaller or larger than the dimension of the substrate 512. As shown in FIG. 8, one embodiment of the invention provides that an outer portion 820 of the substrate support 504 is textured with one or more material layers to prevent particle contamination on the substrate 512.

As mentioned above, any of the one or more internal surfaces of the one or more components of a process chamber can be textured to improve bonding and adhesion of any foreign material or particle generated during substrate processing. Further examples of chamber component for other suitable substrate processing chamber may include dark space shield, support ring, deposition ring, coil, coil supports, deposition collimators, pedestal, alignment ring, shutter disk, etc.

Other process chambers of various configuration and chamber part components thereof can also be textured using methods of the invention to reduce contamination during substrate processing without departing from embodiments of the invention. The contamination can be cleaned away by servicing the chamber part components using suitable chemical cleaning solutions as described herein and each of the chamber components can be re-textured using methods of the invention. In addition, the sizes and dimensions for various components as shown above are illustrative and are not meant to limit the scope of the invention.

While the foregoing is directed to embodiments of the present invention, other and further embodiments of the invention may be devised without departing from the basic scope thereof, and the scope thereof is determined by the claims that follow.

1. A method of reducing contaminants in a process chamber, comprising:
coating one or more surfaces of one or more components of the process chamber with a first material layer having a surface roughness measurement of a first RMS of about 1200 micro-inches or less; and
arc spraying the surface of the first material layer with a second material layer having a surface roughness measurement of a second RMS of about 1500 micro-inches or more to roughen the one or more surfaces of the one or more components, wherein the second RMS is larger than the first RMS.

2. The method of claim 1, further comprising processing a substrate in the process chamber to generate contaminants which bind to the second material layer.

3. The method of claim 1, further comprising chemically cleaning the one or more surfaces of the one or more components.

4. The method of claim 1, wherein the substrate comprises a substrate for flat panel display.

5. The method of claim 1, wherein coating the one or more surfaces of the one or more components comprises a process selected from the group consisting of plating, arc spraying, bead blasting, thermal spraying, plasma spraying, and combinations thereof.

6. The method of claim 1, wherein the materials of the one or more components and the second material layer are the same.

7. The method of claim 1, wherein the material of the one or more components comprises a material selected from the group consisting aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.

8. The method of claim 1, wherein the material of the one or more components comprises aluminum and the material of the first material layer comprises aluminum alloys.

9. The method of claim 1, wherein the material of the one or more components comprises aluminum and the material of the first material layer comprises titanium or its alloys.

10. The method of claim 1, further comprising heating the one or more components.

11. The method of claim 1, wherein the one or more components comprise a work-piece selected from the group consisting of a chamber shield member, a dark space shield, a shadow frame, a substrate support, a target, a shadow ring, a deposition collimator, a chamber body, a chamber wall, a coil, a coil support, a cover ring, a deposition ring, a contact ring, an alignment ring, a shutter disk, and combinations thereof.

12. The method of claim 1, wherein the one or more components comprise a peripheral portion of a substrate support.

13. The method of claim 1, wherein the material of the second material layer comprises a material selected from the group consisting of aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.

14. A method of texturing a surface of a component for use in a semiconductor process chamber, comprising:
coating the surface of the component with a first material layer having a surface roughness measurement of a first RMS; and
arc spraying the surface of the first material layer with a second material layer having a surface roughness measurement of a second RMS of about 1500 micro-inches or more to roughen the surface of the component, the second RMS being larger than the first RMS.

15. A method of texturing a surface of a component for use in a semiconductor process chamber, comprising:
coating the surface of the component with a first material layer having a surface roughness measurement of a first RMS of about 1200 micro-inches or less; and
arc spraying the surface of the first material layer with a second material layer having a surface roughness measurement of a second RMS to roughen the surface of the component, the second RMS being larger than the first RMS.

16. A method of texturing a surface of a component for use in a semiconductor process chamber, comprising:
coating the surface of the component with a protective layer having a surface roughness measurement of a first RMS; and
arc spraying the surface of the protective layer with a material layer having a surface roughness measurement of a second RMS, the material layer comprising the same material as the material of the component and the second RMS being larger than the first RMS.

17. The method of claim 16, wherein the material of the component comprises a material selected from the group consisting of aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.

18. The method of claim 16, wherein the material of the component comprises a metal and the material of the protective layer comprises its alloy.

19. The method of claim 18, wherein the metal comprises aluminum.

20. The method of claim 16, wherein the material of the component comprises aluminum and the material of the protective layer comprises titanium or its alloys.

21. The method of claim 16, wherein coating the surface of the component comprises a process selected from the group consisting of arc spraying, plating, bead blasting, thermal spraying, plasma spraying, and combinations thereof.

22. The method of claim 16, further comprising chemically cleaning the surface of the component prior to coating.

23. The method of claim 16, further comprising chemically cleaning the surface of the component after arc spraying to remove the material layer.

24. A process chamber component for use in a process chamber, comprising:
a body having one or more surfaces;
a first coating formed on the surfaces, the first coating having a first RMS surface roughness measurement of about 1200 micro-inches or less; and
a second coating formed on the surfaces by arc spraying, the second coating having a second RMS surface roughness measurement of about 1500 micro-inches or more to roughen the surface of the component.

25. The process chamber component of claim 24, wherein the second RMS is larger than the first RMS.

26. The process chamber component of claim 24, wherein the process chamber component is selected from the group consisting of a chamber shield member, a dark space shield, a shadow frame, a substrate support, a target, a shadow ring, a deposition collimator, a chamber body, a chamber wall, a coil, a coil support, a cover ring, a deposition ring, a contact ring, an alignment ring, a shutter disk, and combinations thereof.

27. The process chamber component of claim 24, wherein the process chamber component comprises a peripheral portion of a substrate support.

28. The process chamber component of claim 24, wherein the process chamber component is made of a material selected from the group consisting of aluminum, molybdenum, nickel, titanium, tantalum, tungsten, copper, steel, stainless steel, iron-nickel-chromium alloys, nickel-chromium-molybdenum-tungsten alloys, chromium copper alloys, copper zinc alloys, silicon carbide, sapphire, aluminum oxide, aluminum nitride, silicon oxide, quartz, polyimide, polyarylate, polyether, etherketone, and their alloys and combinations thereof.
